(19) United States
(12) Patent Application Publication
(10) Pub. No.: US 2012/0327566 A1
(43) Pub. Date: Dec. 27, 2012

(54) ADJUSTABLE DISPLAY STAND

(76) Inventors: John William Pennington, JR., Mountain View, CA (US); John J Briden, San Francisco, CA (US); Jean G Atallah, Fremont, CA (US)

(21) Appl. No.: 13/165,397

(22) Filed: Jun. 21, 2011

(51) Int. Cl. H05K 7/00; F16M 11/10

(52) U.S. Cl. 361/679.01; 248/122.1

(57) ABSTRACT

Embodiments of the present invention disclose an adjustable display stand. According to one example embodiment, the adjustable display stand includes a base and display support member for mounting a display. An arm support housing is coupled to the display support member at a first pivot position proximate to a first end of the support housing, and to the base unit at second pivot point proximate to a second end of the support housing. Furthermore, tilt adjustment of the display causes rotational movement of both the arm support housing and the display support member at the second pivot position and the first pivot position respectively.

### BACKGROUND

Desktop computer systems are ubiquitous in both business and personal computing environments. Such systems typically include a display monitor and a stand or base element for supporting the monitor. During use of the computing system, an operating user may desire to change to viewing angle of the display. Due to functional and mechanical limitations of today's monitor stands, however, tilt adjustment of the display unit often fails to yield the desired or optimum viewing angle and in some cases creates a potential tipping hazard for the computing system.

### BRIEF DESCRIPTION OF THE DRAWINGS

The features and advantages of the inventions as well as additional features and advantages thereof will be more clearly understood hereinafter as a result of a detailed description of particular embodiments of the invention when taken in conjunction with the following drawings in which:

FIG. 1 is a three-dimensional perspective view of a monitor and adjustable display stand according to an example of the present invention.

FIG. 2 is a sectional view of the adjustable display stand according to an example of the present invention.

FIG. 3A is a side profile view of the adjustable display stand, FIG. 3B is an enlarged sectional view of the roller chain and sprocket, and FIG. 3C is an enlarged sectional view of the roller chain in accordance with an example of the present invention.

FIGS. 4A-4C illustrates a tilt pivot movement into a first reclined position using the adjustable display stand according to an example of the present invention.

FIGS. 5A-5C illustrates a tilt pivot movement into a second reclined position using adjustable display stand according to an example of the present invention.

FIGS. 6A-6C illustrates another tilt pivot action into a third reclined position using the adjustable display stand in accordance with an example of the present invention.

### DETAILED DESCRIPTION OF THE INVENTION

The following discussion is directed to various embodiments. Although one or more of these embodiments may be discussed in detail, the embodiments disclosed should not be interpreted, or otherwise used, as limiting the scope of the disclosure, including the claims. In addition, one skilled in the art will understand that the following description has broad application, and the discussion of any embodiment is meant only to be an example of that embodiment, and not intended to intimate that the scope of the disclosure, including the claims, is limited to that embodiment. Furthermore, as used herein, the designators “A”, “B” and “N” particularly with respect to the reference numerals in the drawings, indicate that a number of the particular feature so designated can be included with examples of the present disclosure. The designators can represent the same or different numbers of the particular features.

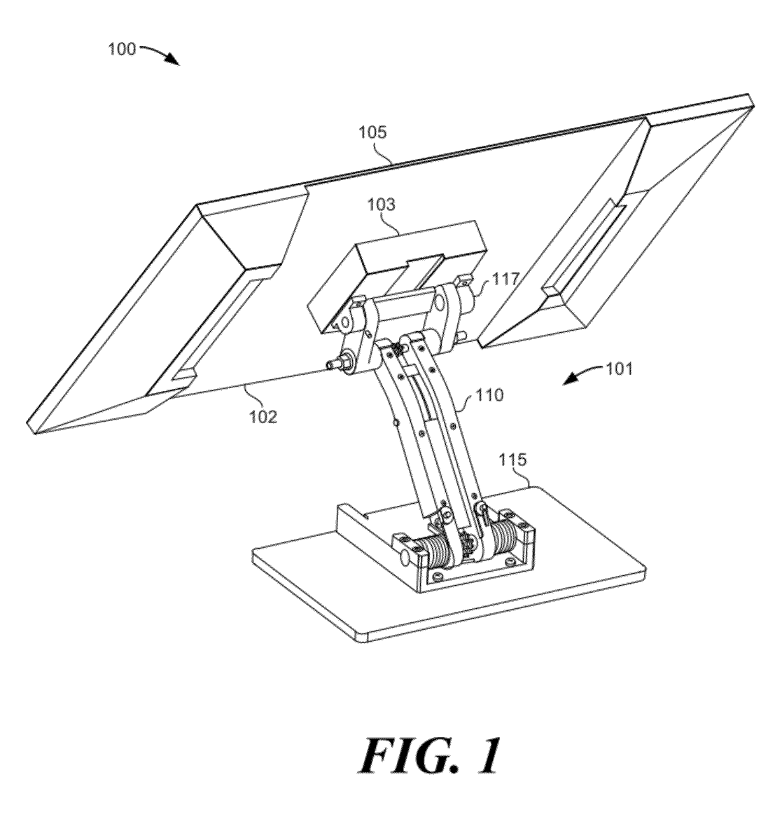

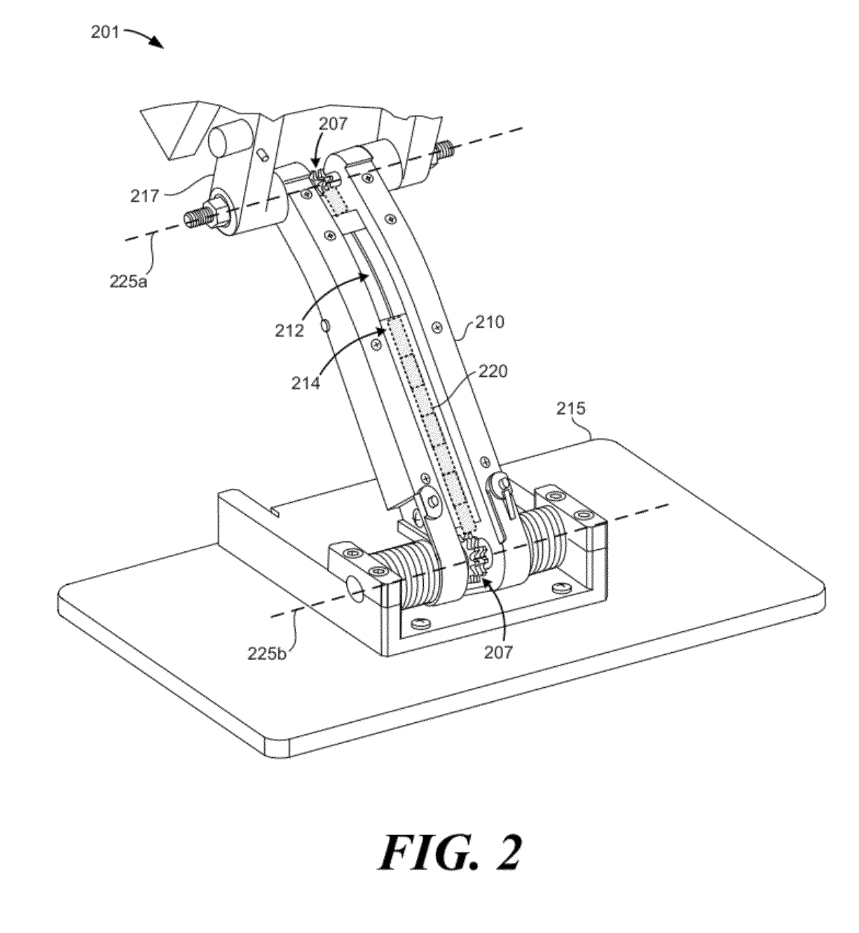

The figures herein follow a numbering convention in which the first digit or digits correspond to the drawing figure number and the remaining digits identify an element or component in the drawing. Similar elements or components between different figures may be identified by the user of similar digits. For example, 143 may reference element “43” in FIG. 1, and a similar element may be referenced as 243 in FIG. 2. Elements shown in the various figures herein can be added, exchanged, and/or eliminated so as to provide a number of additional examples of the present disclosure. In addition, the proportion and the relative scale of the elements provided in the figures are intended to illustrate the examples of the present disclosure, and should not be taken in a limiting sense.

Generally, movement of a display monitor and stand from a high vertical position to a lower reclined position is often preferred by the end user for more ergonomic use of the display. Unfortunately, prior display stand designs often have limited coordination between pivot movements during tilt adjustment. Some display stands attempt to facilitate tilt adjustment using flexible belts and rotating shafts embedded in the display stand. Due to the high loads experienced by the belt mechanism via the display monitor, use of flexible belts and shafts often result in unwanted flexibility in the structure and may cause the stand to bounce during adjustment thus failing to reliably hold the adjusted position. This hazard is sometimes minimized by increasing stand size or weight—undesirable features for compact computer display and stand solutions. Inclusion of a flexible drive shaft has also been contemplated for coordinating movement between pivots, but the drive shaft is costly and its large diameter makes it impractical for use with compact computer stand products.

Other prior solutions attempt to link two rotation movements through the use of a four-bar mechanism. In this solution, two support arms of the four-bar design must be separated to accommodate a large angle of adjustment. As a result, separation distance becomes large resulting in a wide stand structure. In addition, when the display is moved to large angles of recline, the two arms of the four-bar design can come together and create a pinch effect. Unless protected from the end user by altering the distance/size of the two arms, which serves to make the display stand even larger, the pinching effect can be an unpleasant safety hazard.

Examples of the present invention provides an adjustable display stand for computer monitors and all-in-one computers for example. By providing the ability to adjust both the tilt angle and vertical height of the display monitor, a significant ergonomic benefit is provided to the end user. Such coordination is important in order to eliminate the unwanted orientations of large recline angle at a high vertical position and a small recline angle at a low vertical position. The former case makes the system unstable and the latter case can lead to unwanted display contact with the table surface. Examples of the present invention provides an internal roller chain with various-sized sprockets at the two pivot points so as to link the rotation axes and articulate tilt movement and avoid such unwanted conditions.

Referring now in more detail to the drawings in which like numerals identify corresponding parts throughout the views, FIG. 1 is a three-dimensional perspective view of a monitor and adjustable display stand according to an example of the present invention. As shown in the example of FIG. 1, the system 100 includes a display monitor 105 attached to an adjustable display stand 101. The adjustable display stand 101 includes a display attachment means 102 and display mount 103, a rotatable display support member 117, an arm support housing 110, and a stand base unit 115. According to one example, the display unit 105 is affixed to display stand 101 via the display attachment means 102 and display mount 103. The display mount 103 is coupled to the rotatable display support member 117, which is coupled to the arm support housing or structure 110. As will be explained in further detail below, the display support member 117 is coupled to the arm support housing 110 at a first pivot point for providing tilt angle adjustment of the display unit 105. Still further, the base stand unit 115 is coupled to the arm support structure 110 at a lower second pivot position for providing vertical height adjustment of the display unit 105.

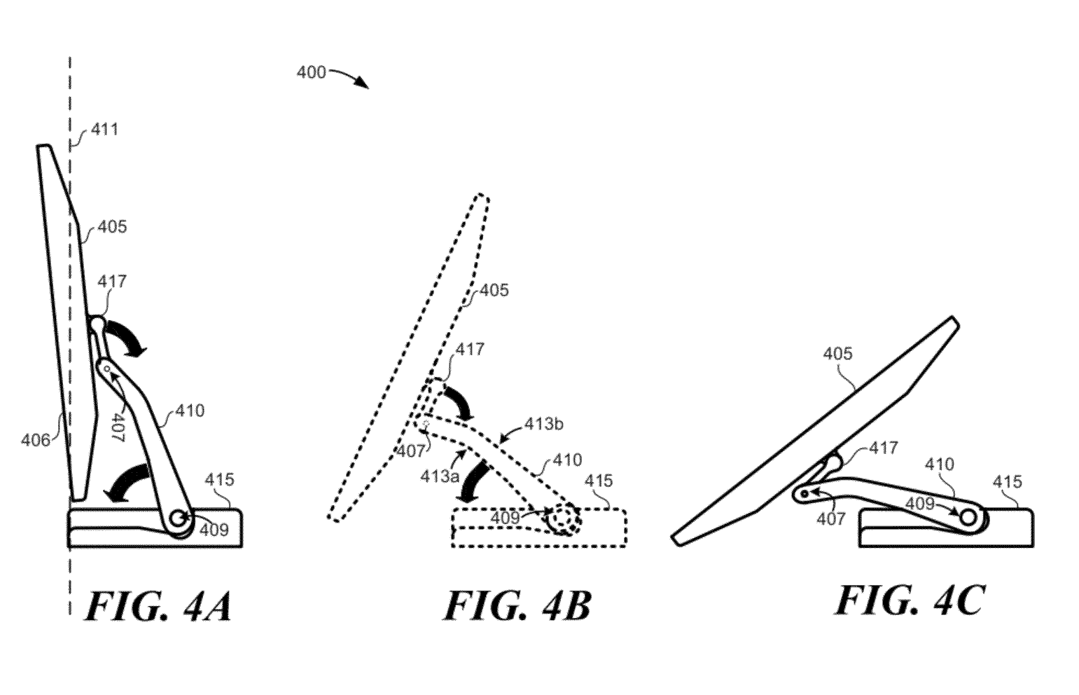

FIG. 2 is a sectional view of the adjustable display stand according to an example of the present invention. In the present example, the display stand 201 includes a rotatable support member 217 connected to the arm support housing 210 of the display stand 201 at a first pivot point 225a. A roller chain 220 and upper and lower sprockets 207 and 209 are housed within the arm support housing 210 so as to hide the display adjustment mechanism from the end user. In the present example, the support member 217 is configured to rotate and pivot about the horizontal axis of rotation (dotted line) at pivot point 225a. In addition, upper sprockets 207 are formed at the upper junction of the support member 217 and the support arm 210 so as to correspond with the pivot point or axis of rotation 225a. Similarly, lower sprockets 209 are formed at a lower junction of the support arm housing 210 and the base 215 so as to correspond with a second pivot point or axis of rotation 225b. Furthermore, a roller chain 220 connects the rotation mechanism between the lower and upper sprockets 207 and 209 located at the pivot points 225a and 225b of the adjustable pivot stand 201. According to one example, sufficient tensioning of the roller chain 220 is accomplished by lateral displacement of the roller chain 220 via the chain tensioner 212. Through this configuration, movement of the display by the end user forces rotation about both pivot points 225a and 225b. As will be described in further detail with reference to FIGS. 4A-6C, sprocket rotation at one pivot point (e.g., 225b) causes contemporaneous sprocket rotation at the other pivot point (e.g., 225a) through movement of the roller chain 220 along the chain path 214, which corresponds with the longitudinal side of arm support 210.

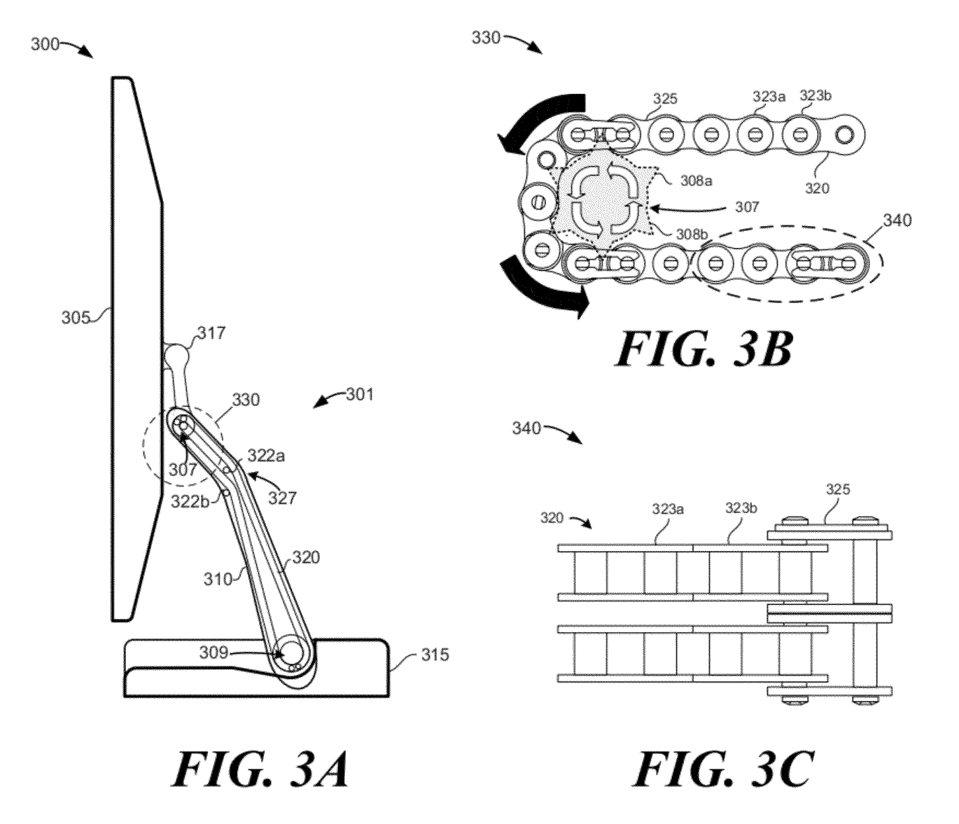

FIG. 3A is a side profile view of the adjustable display stand according to an example of the present invention. As shown here, the system 300 includes a display unit or monitor 305 attached to the adjustable display stand 301. According to the present example, the display unit 305 is coupled to the arm support housing 310 via the rotatable display support member 317. The upper sprockets 307 and lower sprockets 309 are positioned on opposite ends of the arm support housing 310, with the upper sprockets 307 being formed proximate to the display unit 305 and the lower sprockets 309 formed proximate to the base housing 315. Moreover, sprocket idlers 322a and 322b may also be included within the arm support housing 310 for facilitating smooth transitional movement of the roller chain 320 around the bent area 327 of the arm support housing 310.

FIG. 3B is an enlarged view 330 of the upper sprocket 307 and roller chain 320, while FIG. 3C is an enlarged and top-down view of a section 340 of the roller chain according to an example of the present invention. As shown here, the roller chain 320 includes a plurality of rollers 323a and 323b and chain links 325. In one example, the roller chain 320 represents a American National Standards Institute (ANSI) size 25 or 25-2 double strand roller chain (FIG. 3C) or bush roller chain. The upper sprocket 307 may represent a six-tooth sprocket 307 for interlocking with the links 325 and cylindrical rollers 323a and 323b of the roller chain 320 (lower sprocket 309 may represent a larger twelve-tooth sprocket). As depicted by the directional arrows of FIG. 3B, movement of either the upper sprocket 307 or the lower sprocket 309 causes simultaneous rotational movement (clockwise or anticlockwise) of the opposite sprocket (i.e., either sprocket 307 or 309) and therefore rolling movement of the roller chain 320 via contact of the individual rollers (323a and 323b) with the teeth (e.g., 308a and 308b) of each sprocket.

FIGS. 4A-4C illustrates a tilt pivot movement into a first reclined position using the adjustable display stand according to an example of the present invention. In the example of FIG. 4A, the system 400 and display are at a negative inclined tilt position (e.g., −5 degrees tilt). More specifically, the display unit 405 is vertically tilted about minus five degrees with respect to the vertical central axis 411 of the display unit 405. Here, movement of the display unit 405 away from the user or the front surface 406 thereof, causes the display unit 405 to rotate about the second pivot position (225b of FIG. 2) associated with the lower sprocket 409. Accordingly, rotation of the lower sprocket 409 causes the roller chain to move and impart rotation at the first pivot position (225a of FIG. 2) associated with the upper sprocket 407. As indicated by the directional arrows of FIG. 4A and transitional FIG. 4B, such action causes the arm support housing 410 to move in a first direction and downwards such that a facing side 413a of the arm support housing 410 abuts (or nearly abuts) the base unit 415 while the display support member 417 and display unit 405 moves in an opposite second direction and downward such that the display support member 417 abuts (or nearly abuts) a rear side 413b of the arm support housing 410. As shown here, after dual pivot movement of the display support member 417 and arm support housing 410, the display unit 405 is now in a first reclined positioned, which may be about sixty degrees with respect to the base member 415.

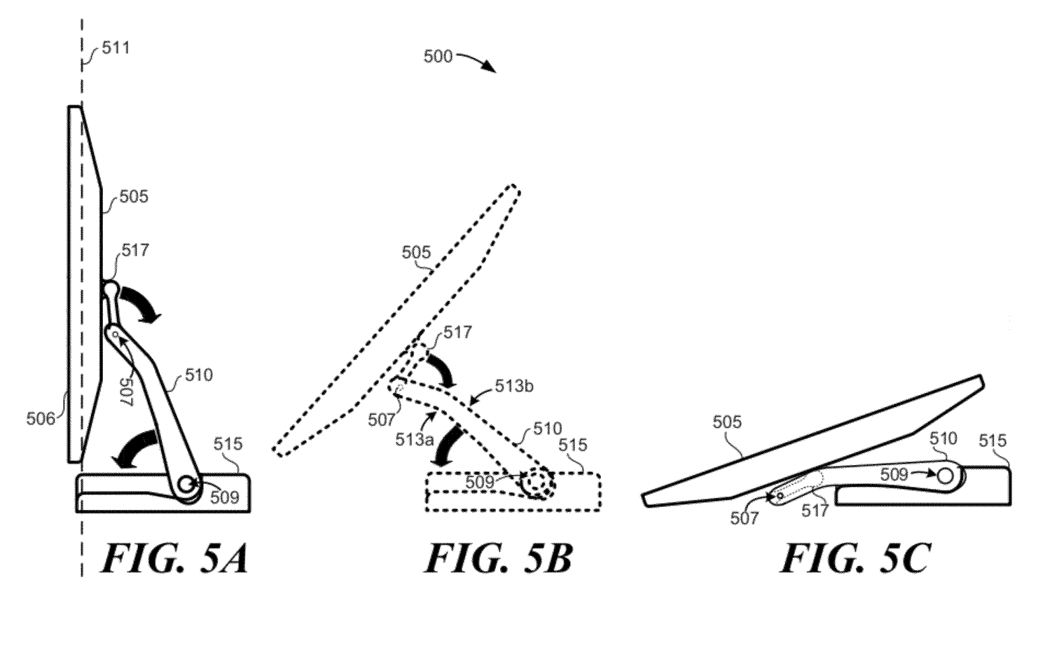

FIGS. 5A-5C illustrates a tilt pivot movement into a second reclined position using adjustable display stand according to an example of the present invention. In the example of FIG. 5A, the system 500 and display unit 505 are at a non-tilted position (i.e., 0 degree tilt). More specifically, the display unit 505 is aligned with the vertical central axis 511 of the display unit 505. Here, movement of the display unit 505 away from the user or the front surface 506 thereof, causes the display unit 505 to rotate about the second pivot position (225b of FIG. 2) associated with the lower sprocket 509. As in the previous example, rotation of the lower sprocket 509 causes the roller chain to move and impart rotation at the first pivot position (225a of FIG. 2) associated with the upper sprocket 507. Moreover and as depicted by the directional arrows of FIG. 5A and FIG. 5B, such action causes the arm support housing 510 to move in a first direction and downwards such that a facing side 513a of the arm support housing 510 abuts (or nearly abuts) the base unit 515 while the display support member 517 and display unit 505 move in an opposite second direction and downward such that the display support member 517 abuts (or nearly abuts) a rear side 513b of the arm support housing 510. As a result of dual pivot action of the display support member 517 and arm support housing 510 about the first and second pivot positions respectively, the display unit 505 is now in a second reclined positioned, which may be about fifteen degrees with respect to the base member 515.

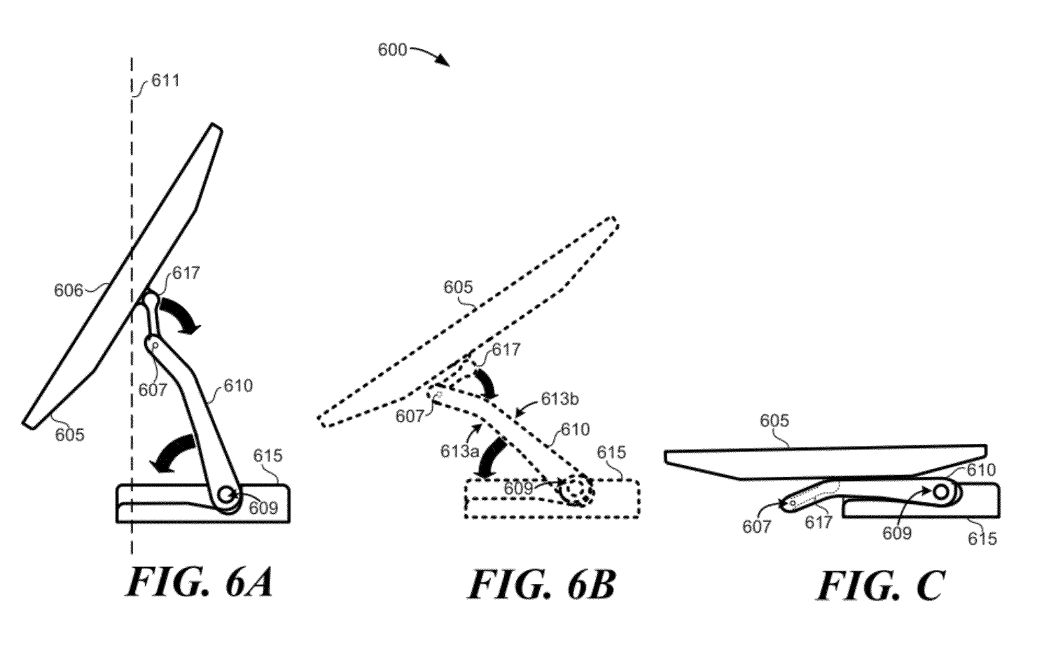

FIGS. 6A-6C illustrates yet another tilt pivot action into a third reclined position using the adjustable display stand according to an example of the present invention. As shown here, the system 600 and display unit 605 are at a positive titled position (e.g., 19 degree tilt). According to one example embodiment, the display unit 605 is titled at an angle of nineteen degrees with respect to the vertical central axis 611 of the display unit 605. In the present example, positional movement of the display unit 605 by the end user away from the user or the front surface 606 thereof, causes the display unit 605 to rotate about the second pivot position (225b of FIG. 2) associated with the lower sprocket 609. Here, rotation of the lower sprocket 609 causes the roller chain to move and impart rotation at the first pivot position (225a of FIG. 2) associated with the upper sprocket 607. As indicated by the directional arrows of FIG. 6A and FIG. 6B, such action causes the arm support housing 610 to move in a first direction and downwards such that a facing side 613a of the arm support housing 610 completely abuts the base unit 615, while the display support member 617 and display unit 605 move in an opposite second direction and downward such that the display unit 605 abuts a rear side 613b of the arm support housing 610. As shown here, dual pivot movement of the display support member 617 and arm support housing 610 about the first and second pivot positions respectively, causes the display unit 605 to now rest in a fully-reclined position, or parallel to the base member 615.

Many advantages are afforded by adjustable display stand in accordance with examples of the present invention. For instance, when desired by the end user for ergonomic use, the roller chain and sprocket design of the present example provides simplified articulation of the display unit from a high vertical position to a lower reclined position. Moreover, the sprockets and roller chain are strong and inexpensive thereby simplifying and reducing manufacturing costs. In addition, the small size of roller chain allows for easy placement and positioning of the roller chain within the arm support structure, thus providing a minimum arm size and hiding the roller mechanism from the end or operating user.

Furthermore, while the invention has been described with respect to exemplary embodiments, one skilled in the art will recognize that numerous modifications are possible. For example, although example embodiments depict a flat panel display monitor as the representative display unit, the invention is not limited thereto. For example, the display unit may be an all-in-one personal computer, a television monitor, tablet personal computer, or any other electronic device having a display unit for viewing by an end user.

Furthermore, the number of sprockets can vary based on the rate of one pivot rotation relative to the other. Moreover, modifying the length of the support arm between the connecting pivots can make a wide range of adjustment positions possible. Thus, although the invention has been described with respect to example embodiments, it will be appreciated that the invention is intended to cover all modifications and equivalents within the scope of the following claims.

What is claimed is:

1. An adjustable display stand comprising:
a display support member for mounting a display;
a base unit;
an arm support housing connected to the display support member at a first pivot position proximate to a first end of the support housing, and to the base unit at second pivot position proximate to a second end opposite the first end; and
wherein tilt adjustment of the display causes rotational movement of both the arm support housing and the display support member at the second pivot position and the first pivot position respectively.

2. The display stand of claim 1, wherein the first pivot position affects tilt angle adjustment of the display while the second pivot position affects vertical height adjustment of the display.

3. The display stand of claim 1 further comprising:
a roller chain including a plurality of roller elements housed with the arm support housing and configured to move along a chain path for facilitating adjustment of the display from an upright viewing position to a reclined viewing position.

4. The display stand of claim 3, further comprising:
at least one upper sprocket including a plurality of teeth and housed within the arm support housing at the first pivot position; and
at least one lower sprocket including a plurality of teeth and housed within the arm support housing at the second pivot position.

5. The display stand of claim 4, wherein the plurality of teeth of the upper sprocket and the plurality of teeth of the lower sprocket are configured to engage with the plurality of roller elements of the roller chain.

6. The display stand of claim 5, wherein adjustment movement of the display causes the lower sprocket and teeth thereof to rotate so as to cause movement of the roller chain and impart contemporaneous rotation of the at least one upper sprocket.

7. The display stand of claim 6, wherein upon movement of the display away from the operating user, the arm support housing moves downward in a first direction and the display support member moves downward in a second direction opposite the first direction.

8. The display stand of claim 6, wherein adjustment movement of the display to a reclined viewing position includes a facing side of the arm support housing moving towards the base unit contemporaneously with the display and display support member moving toward a rear side of the display support arm.

9. The display stand of claim 1, wherein the display is capable of being placed in a fully-reclined position in which the display is parallel with the base unit.

10. The display stand of claim 1, further comprising:
a plurality of idler sprockets positioned within the arm support housing at a bent area for facilitating sliding movement of the roller chain along the chain path.

11. A display support stand system comprising:
a display unit
a base member;
a display support structure affixed to a rear side of the display unit;
an stand support member coupled to the display support structure at a first pivot position proximate to a first end of the stand support member, and to the base unit at second pivot point proximate to a second end opposite the first end; and
a roller chain including a plurality of roller elements housed with the arm support housing and configured to move along a chain path for facilitating adjustment of the display from an upright viewing position to a reclined viewing position,
wherein tilt adjustment of the display unit by an operating user causes rotational movement of both the stand support member and the support structure at the second pivot position and the first pivot position respectively.

12. The system of claim 11, wherein the first pivot position affects tilt angle adjustment of the display unit while the second pivot position affects vertical height adjustment of the display unit.

13. The system of claim 11, further comprising:
at least one upper sprocket including a plurality of teeth and housed within the arm support housing at the first pivot position; and
at least one lower sprocket including a plurality of teeth and housed within the arm support housing at the second pivot position.

14. The system of claim 13, wherein the plurality of teeth of the upper sprocket and the plurality of teeth of the lower sprocket are configured to engage with the plurality of roller elements of the roller chain.

15. The system of claim 14, wherein adjustment movement of the display causes the lower sprocket and teeth thereof to rotate so as to cause movement of the roller chain along the chain path and impart contemporaneous rotation of the at least one upper sprocket.

16. The system of claim 15, wherein upon movement of the display away from the operating user, the arm support housing moves downward in a first direction and the display support member moves downward in a second direction opposite the first direction.

17. The system of claim 15, wherein adjustment movement of the display unit to a reclined viewing position includes a facing side of the arm support housing moving towards the base unit contemporaneously with the display and display support member moving toward a rear side of the display support arm.

18. The system of claim 11, wherein the display unit is capable of being placed in a fully-reclined position in which the display unit is parallel with the base unit.
